(19) United States
(12) Patent Application Publication
(10) Pub. No.: US 2025/0275351 A1
(43) Pub. Date: Aug. 28, 2025

(54) LIGHT EMITTING DEVICE AND LIGHT EMITTING DISPLAY DEVICE INCLUDING THE SAME

(71) Applicant: LG Display Co., Ltd., Seoul (KR)

(72) Inventors: Sang Kyoung MOON, Paju-si (KR); Bo A JIN, Paju-si (KR); Ki Min LIM, Paju-si (KR); Seung Kwang ROH, Paju-si (KR); Chi Hak LEE, Paju-si (KR)

(73) Assignee: LG Display Co., Ltd., Seoul (KR)

(21) Appl. No.: 19/006,810

(22) Filed: Dec. 31, 2024

(30) Foreign Application Priority Data
Feb. 27, 2024 (KR) 10-2024-0028392

(51) Int. Cl. H10K 50/13; H10K 50/12; H10K 50/818; H10K 50/828; H10K 101/30

(52) U.S. Cl. CPC H10K 50/13; H10K 50/12; H10K 50/818; H10K 50/828; H10K 2101/30

(57) ABSTRACT

A light emitting device can include an anode, a plurality of light emitting stacks provided to overlap with a charge generation layer interposed therebetween, and a cathode provided on the plurality of light emitting stacks. Each of the plurality of light emitting stacks includes a light emitting layer configured to emit light of a color of the same series, and the light emitting layer of at least one of the plurality of light emitting stacks includes a first sub-light emitting layer and a second sub-light emitting layer in contact with each other. The second sub-light emitting layer has a greater dopant content than the first sub-light emitting layer.

### CROSS-REFERENCE TO RELATED APPLICATIONS

This application claims priority to Korean Patent Application No. 10-2024-0028392, filed in the Republic of Korea on Feb. 27, 2024, the entire contents of which are hereby expressly incorporated by reference as if fully set forth herein into the present application.

### BACKGROUND OF THE DISCLOSURE

### Field

The present disclosure relates to a light emitting device and a light emitting display device including the same.

### Discussion of the Related Art

Recently, a light emitting display device which does not require any separate light source and has light emitting devices within a display panel for compactness of the device and clear color display is being considered as a competitive display device for various applications.

Light emitting devices used in the light emitting display device need to have higher efficiency in order to realize high image quality.

Further, in order to increase efficiency of the color of light emitted by each subpixel, light emitting devices having a tandem structure in which light emitting layers for emitting light of a color of the same series are provided in different stacks of each subpixel, are being considered.

### SUMMARY OF THE DISCLOSURE

Accordingly, the present disclosure is directed to a light emitting device and a light emitting display device including the same that substantially obviate one or more problems due to limitations and disadvantages of the related art.

In a light emitting device having a tandem structure in which light emitting layers emitting light of the same color are provided in a plurality of stacks, an inflection section where a difference in efficiency occurs for the same color coordinates can occur.

An object of the present disclosure is to provide a light emitting device and a light emitting display device including the same that adjust the configuration of light emitting layers for each light emitting stack to minimize or prevent occurrence of an inflection section and simultaneously improve efficiency and color purity.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the disclosure, as embodied and broadly described herein, a light emitting device includes an anode, a plurality of light emitting stacks provided on the anode and configured to overlap with a charge generation layer interposed therebetween, and a cathode provided on the plurality of light emitting stacks.

In aspects of the present disclosure, each of the plurality of light emitting stacks can include a light emitting layer configured to emit light of a color of the same series, the light emitting layer of at least one of the plurality of light emitting stacks can include a first sub-light emitting layer and a second sub-light emitting layer in contact with each other, and the second sub-light emitting layer can have a greater dopant content than the first sub-light emitting layer.

In another aspect of the present disclosure, a light emitting display device includes a blue light emitting device, a green light emitting device, and a red light emitting device provided in a first subpixel, a second subpixel, and a third subpixel on a substrate, each of the blue, green, and red light emitting devices including a plurality of light emitting stacks between an anode and a cathode, wherein, in at least one of the blue light emitting device, the green light emitting device, or the red light emitting device, a light emitting layer of at least one of the plurality of light emitting stacks includes a first sub-light emitting layer and a second sub-light emitting layer in contact with each other.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a cross-sectional view showing a light emitting device according to one or more embodiments of the present disclosure;

FIG. 2 is a graph showing the electroluminescence spectrum of a blue light emitting device depending on a doping amount of a blue dopant;

FIG. 3 is a graph showing the normalized intensity of the electroluminescence spectrum of the blue light emitting device depending on the doping amount of the blue dopant;

FIG. 4 is a schematic diagram comparatively showing efficiencies of respective light emitting stacks of the light emitting device according to one or more embodiments of the present disclosure;

FIG. 5 is a graph showing intensity influences of the respective light emitting layers of FIG. 4;

FIG. 6 is a graph showing efficiency influences of the respective light emitting layers of FIG. 4;

FIG. 7A to 7C show examples in which the light emitting layer of the light emitting device of the present disclosure includes a plurality of sub-light emitting layers;

FIG. 8 shows embodiments of the present disclosure in which, if the light emitting layer of the light emitting device of the present disclosure includes a plurality of sub-light emitting layers, hosts of adjacent sub-light emitting layers are different;

FIG. 9 is a graph showing efficiency of the blue light emitting device depending on a doping amount;

FIG. 10 is a graph showing efficiency of a green light emitting device depending on a doping amount;

FIG. 11 is a graph showing efficiency of a red light emitting device depending on a doping amount;

FIG. 12 is a cross-sectional view showing a light emitting display device according to one or more embodiments of the present disclosure; and

FIG. 13 is a detailed cross-sectional view showing the light emitting display device according to one or more embodiments of the present disclosure.

### DETAILED DESCRIPTION OF THE EMBODIMENTS

Reference will now be made in detail to example embodiments of the present disclosure, examples of which are illustrated in the accompanying drawings. Wherever possible, the same reference numbers will be used throughout the drawings to refer to the same or like parts, unless otherwise specified.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted or may be provided briefly. In addition, the names of elements used in the following description are selected in consideration of clarity of description of the present application, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present application, where terms such as “including,” “having,” “comprising,” and the like are used, one or more components can be added, unless the term, such as “only,” is used. As used herein, the term “and/or” includes a single associated listed item and any and all of the combinations of two or more of the associated listed items. Further, the term “can” fully encompasses all the meanings and coverages of the term “may.”

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate (ly)” or “direct (ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate (ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the application, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

In the following description of the present disclosure, the Lowest Unoccupied Molecular Orbital (LUMO) energy level and the Highest Occupied Molecular Orbital (HOMO) energy level of a layer mean the LUMO energy level and the HOMO energy level of a material constituting a major weight ratio of the corresponding layer, unless they refer to the LUMO energy level and the HOMO energy level of a dopant material doping the corresponding layer.

In the following description of the present disclosure, a HOMO energy level can be obtained by measuring a voltage corresponding to a first peak at which electrons are emitted from a material through cyclic voltammetry (CV) for the material to be measured, compared to a reference material whose HOMO energy level is known. Herein, the electron that first comes out of the material is the weakest bound electron, e.g., the outermost electron, and is in the state of the HOMO energy level. For example, the HOMO level of a material can be measured using ferrocene having known oxidation potential value and reduction potential value.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. All the components of each device and each apparatus according to all embodiments of the present disclosure are operatively coupled and configured. Further, in adding reference numerals to elements of each of the drawings, although the same elements are illustrated in other drawings, like reference numerals can refer to like elements. Furthermore, for convenience of description, a scale in which each of elements is illustrated in the accompanying drawings can differ from an actual scale. Thus, the illustrated elements are not limited to the specific scale in which they are illustrated in the drawings.

A light emitting stack in the present disclosure refers to a unit structure including common layers including a hole transport layer and an electron transport layer, and a light emitting layer disposed between the hole transport layer and the electron transport layer, unless limited to a specific structure in one embodiment. The common layers can further include a hole injection layer, an electron blocking layer, a hole blocking layer, and an electron injection layer, and can further include other common layer(s) having other functions depending on the structure or design of a light emitting device.

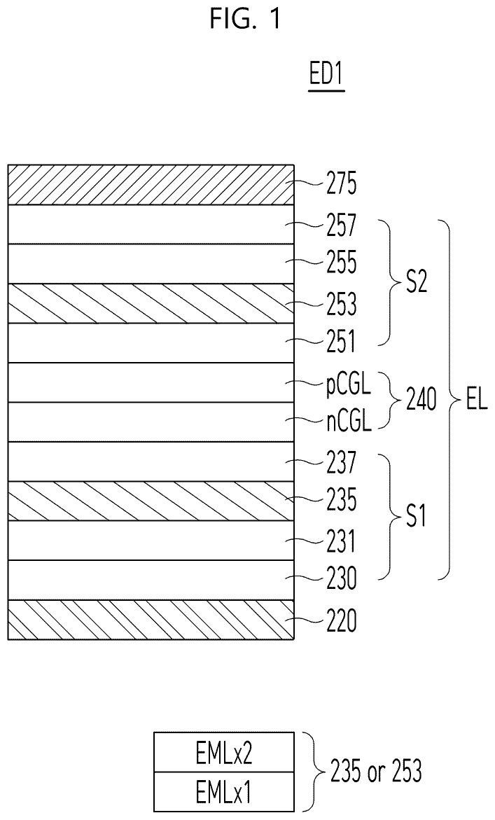

FIG. 1 is a cross-sectional view showing a light emitting device according to one or more embodiments of the present disclosure.

As shown in FIG. 1, a light emitting device ED1 according to one or more embodiments of the present disclosure includes an anode 220, first and second light emitting stacks S1 and S2 provided on the anode 220 and overlapping with a charge generation layer 240 interposed therebetween, and a cathode 275 provided on the second light emitting stack S2. That is, the first light emitting stack S1 may be disposed between the anode 220 and the charge generation layer 240, and the second light emitting stack S2 may be disposed between the charge generation layer 240 and the cathode 275.

In the light emitting device ED1 according to one or more embodiments shown in FIG. 1, the light emitting stacks S1 and S2 are stacked to achieve high efficiency and long lifespan. An example in which two light emitting stacks S1 and S2 are provided between the anode 220 and the cathode 275 is shown, but the light emitting device ED1 is not limited to this example, and can also be changed to a structure in which three or more light emitting stacks are stacked.

The first and second light emitting stacks S1 and S2 include light emitting layers 235 and 253 that emit light of a color of the same series, respectively.

More specifically, the first light emitting stack S1 includes a hole injection layer 230, a first hole transport layer 231, a first light emitting layer 235, and a first electron transport layer 237 stacked in the order or in the reverse order, without being limited thereto.

The second light emitting stack S2 includes a second hole transport layer 251, a second light emitting layer 253, a second electron transport layer 255, and an electron injection layer 257 stacked in the order or in the reverse order, without being limited thereto.

A charge generation layer 240 can include an n-type charge generation layer nCGL which generates and transfers electrons, and a p-type charge generation layer pCGL which generates and transfers holes.

One of the anode 220 and the cathode 275 can be a reflective electrode, and the other can be a transparent electrode or a transflective electrode. In Examples of the present disclosure, tests were conducted on examples in which the anode 220 includes a reflective electrode and the cathode 275 includes a transparent electrode or a transflective electrode, without being limited thereto.

The anode 220 can include a stacked structure of a transparent electrode and a reflective electrode, and the cathode 275 can be a transparent electrode or a transflective electrode. For example, the anode 220 can include a stack of ITO/Ag—Pb—Cu (APC)/ITO, and the cathode 275 can include an Ag—Mg alloy layer.

The anode 220 can be connected to a thin film transistor provided on a substrate to selectively receive a signal supplied to each subpixel, and the cathode 275 can be provided in common in the subpixels to receive a common voltage.

The hole injection layer 230 can be formed of a hole injection material of a single organic or inorganic component, or can be formed by adding a p-type dopant to a hole transporting material. The hole injection layer 230 serves to reduce a barrier in supply of holes from the anode 220 to an intermediate layer EL.

The first and second hole transport layers 231 and 251 can be formed of, for example, an amine-based hole transporting material. The first and second hole transport layers 231 and 251 transfer holes injected through the hole injection layer 230 and the charge generation layer 240 toward the first and second light emitting layers 235 and 253.

The electron injection layer 257 is located in contact with the cathode 275, and serves to reduce a barrier in injection of electrons from the cathode 275 to the intermediate layer EL. The electron injection layer 257 can include a halogen atom combined with an alkali metal or an alkaline earth metal, or an electron transporting material.

The first and second electron transport layers 237 and 255 can be formed of, for example, an anthracene-based electron transporting material. The first electron transport layer 237 and the second electron transport layer 255 transfer electrons injected from the charge generation layer 240 and the electron injection layer 257 toward the first and second light emitting layers 235 and 253, respectively.

The hole injection layer 230 can be provided only in the first stack S1 closest to the anode 220.

Further, all the layers between the anode 220 and the cathode 275 are referred to as the intermediate layer EL. That is, the intermediate layer EL may comprise the light emitting stacks S1 and S2 and charge generation layer 240 disposed therebetween.

The electron injection layer 257 can be provided only in the second stack S2 closest to the cathode 275, without being limited thereto.

Other than the two light emitting stacks shown in FIG. 1, three or more light emitting stacks can be provided in the intermediate layer EL.

When n light emitting stacks (n being a natural number of 2 or more) are provided in the intermediate layer EL, an electron injection layer can be provided in an n^{th} light emitting stack closest to the cathode 275.

When n light emitting stacks (n being a natural number of 2 or more) are provided in the intermediate layer EL, a hole injection layer may be provided in an n^{th} light emitting stack closest to the anode 220.

In the light emitting device Eda according to one or more embodiments of the present disclosure, when an electric field is generated by a voltage difference between the anode 220 and the cathode 275, holes transferred through the hole injection layer 230 and the first and second hole transport layers 231 and 251 and electrons transferred through the electron injection hole 257 and the first and second electron transport layer 237 and 255 of the respective light emitting stacks are recombined to produce excitons, and the produced excitons fall to the energy level of the ground state, and emits light in this process.

The light emitting device ED1 shown in FIG. 1 according to the embodiment is characterized in that, when a plurality of light emitting stacks is provided, a light emitting layer provided in each of the light emitting stacks emits light of a color of the same series, and the doping amount of the light emitting layer is adjusted depending on each light emitting stack so as to exhibit the optimal efficiency without an inflection point.

For this purpose, as shown in FIG. 1, at least one of the first light emitting layer 235 or the second light emitting layer 253 can include a first sub-light emitting layer EMLx1 and a second sub-light emitting layer EMLx2, which are in contact with each other. Also, the first sub-light emitting layer EMLx1 and the second sub-light emitting layer EMLx2 may be formed of different materials as the host or the dopant, thereby being capable of reducing sensitivity to occurrence of the inflection section.

In addition, in the light emitting device according to one or more embodiments of the present disclosure, in at least one of the first light emitting layer 235 or the second light emitting layer 253, the second sub-light emitting layer EMLx2 can have a greater content than the first sub-light emitting layer EMLx1 in the stacked structure of the first and second sub-light emitting layers EMLx1 and EMLx2. Thereby, the efficiency of the light emitting device can be improved.

Hereinafter, the effects of the light emitting device and a light emitting display device according to the present disclosure will be examined through tests.

For example, in the case of a light emitting device that emits blue light, generally, as a color coordinate CIEy value decreases, color purity increases. However, a section where efficiency decreases occurs under the condition that the color coordinate CIEy value decreases or remains the same, and such a section is called an inflection section.

When the light emitting device ED1 of FIG. 1 was applied as a blue light emitting device and the contents of the dopant in the first light emitting layer 235 and the second light emitting layer 253 were varied, as set forth in Table 1 below, the following effects were obtained.

TABLE 1

| | Dopant content | Blue dopant | | Blue characteristics | | | |
|---|---|---|---|---|---|---|---|
| | of light | amount(vol %) | | Driving | Efficiency | | |
| Category | emitting layer | EML1 | EML2 | voltage [V] | (Cd/A) | CIEx | CIEy |
| EX1 | EML1 = EML2 | 2 | 2 | 7.3 | 10.2 | 0.139 | 0.070 |
| EX2 | EML1 > EML2 | 3 | 1 | 7.4 | 9.6 | 0.140 | 0.067 |
| EX3 | EML1 < EML2 | 1 | 3 | 7.4 | 8.9 | 0.140 | 0.069 |

Examples 1 to 3 EX1, EX2, and EX3 had the structure shown in FIG. 1, and respective light emitting layers EML1 and EML2 were blue light emitting layers.

In addition, each of Examples 1 to 3 EX1, EX2, and EX3 included the anode 220 and the cathode 275, and the cathode 275 included a transflective electrode to emit light in the top emission manner.

In Examples 1 to 3 EX1, EX2, and EX3, the light emitting layers EML1 and EML2 were formed of the same material to have the same thickness, except that only the contents of a blue dopant were different. In Example 1 to 3 EX1, EX2, and EX3, each of the light emitting layers EML1 and EML2 was a single layer.

In Example 1 EX1 of Table 1, the amount of the blue dopant in the first light emitting layer EML1 of the first light emitting stack and the amount of the blue dopant in the second light emitting layer EML2 of the second light emitting stack were set to the same value, i.e., 2 vol %, and as a result, a driving voltage was 7.3 V, efficiency was 10.2 Cd/A, and a color coordinate CIEx value was 0.139, and a color coordinate CIEy value was 0.070.

In Example 2 EX2 of Table 1, the amount of the blue dopant in the first light emitting layer EML1 of the first light emitting stack was set to 3 vol % and the amount of the blue dopant in the second light emitting layer EML2 of the second light emitting stack was set to 1 vol %, and as a result, a driving voltage was 7.4 V, efficiency was 9.6 Cd/A, and a color coordinate CIEx value was 0.140, and a color coordinate CIEy value was 0.067. In Example 2 EX2, it can be seen that the amount of the dopant in the first light emitting layer EML1 of the first light emitting stack close to the anode 220 was greater than the amount of the dopant in the second light emitting layer EML2 of the second light emitting stack. Thereby, the color coordinate CIEy value of Example 2 EX2 was lower than that of Example 1 EX1, the driving voltage of Example 2 EX2 was almost equal to that of Example 1 EX1, and the efficiency was slightly lower than Example 1 EX1, but the color coordinate of Example 2 EX2 characteristics were improved.

In Example 3 EX3 of Table 1, the amount of the blue dopant in the first light emitting layer EML1 of the first light emitting stack was set to 1 vol % and the amount of the blue dopant in the second light emitting layer EML2 of the second light emitting stack was set to 3 vol %, and as a result, a driving voltage was 7.4 V, efficiency was 8.9 Cd/A, a color coordinate CIEx value was 0.140, and a color coordinate CIEy value was 0.069. In Example 3 EX3, it can be seen that the amount of the dopant in the second light emitting layer EML2 of the second light emitting stack was greater than the amount of the dopant in the first light emitting layer EML1 of the first light emitting stack close to the anode 220, and thereby, the color coordinate CIEy value was lower than that of the Example 1 EX1 but a difference therebetween was not great compared to Example 2 EX2, a decrease in the efficiency of Example 3 EX3 to the efficiency of Example 1 EX1 was 13%, and the efficiency decrease was great compared to the improvement in the color coordinate characteristics.

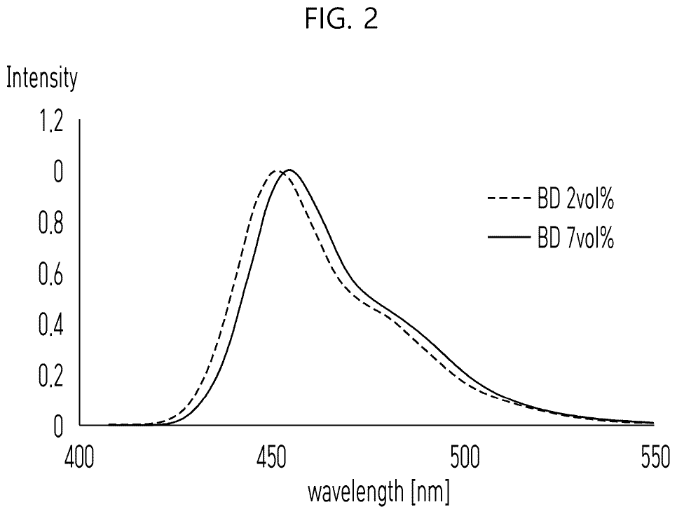

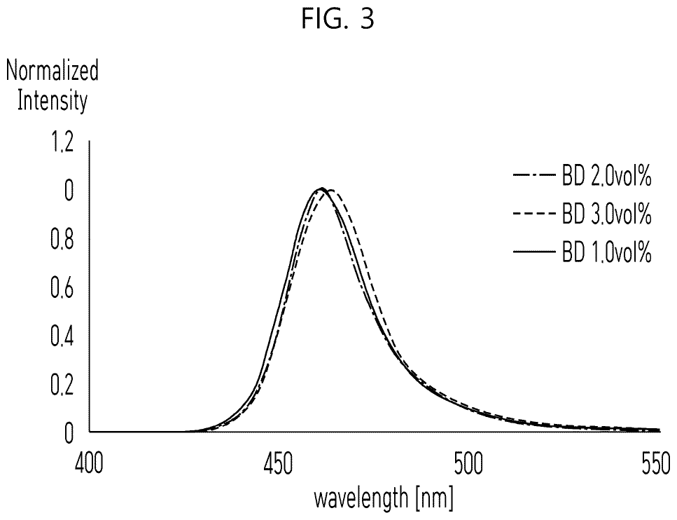

FIG. 2 is a graph showing the electroluminescence spectrum of the blue light emitting device depending on the doping amount of the blue dopant, and FIG. 3 is a graph showing the normalized intensity of the electroluminescence spectrum of the blue light emitting device depending on the doping amount of the blue dopant.

A structure to which FIGS. 2 and 3 are applied is the structure shown in FIG. 1, and the light emitting layers 235 and 253 of the first and second light emitting stacks S1 and S2 are blue light emitting layers having the same blue dopant content.

As shown in FIGS. 2 and 3, as the blue dopant content increases, the electroluminescence (EL) spectrum tends to shift to a longer wavelength. For example, even if the first and second light emitting layers 235 and 253 use the same materials, i.e., the same host and the same dopant, when the content of the blue dopant BD increases, energy transfer from the host to the dopant in the light emitting layer increases or interaction between dopant atoms increases, and a wavelength at which the peak of the EL spectrum occurs tends to shift to a longer wavelength.

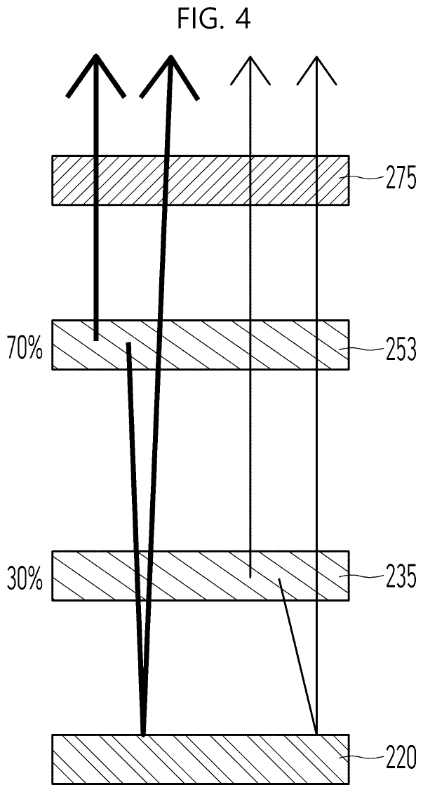

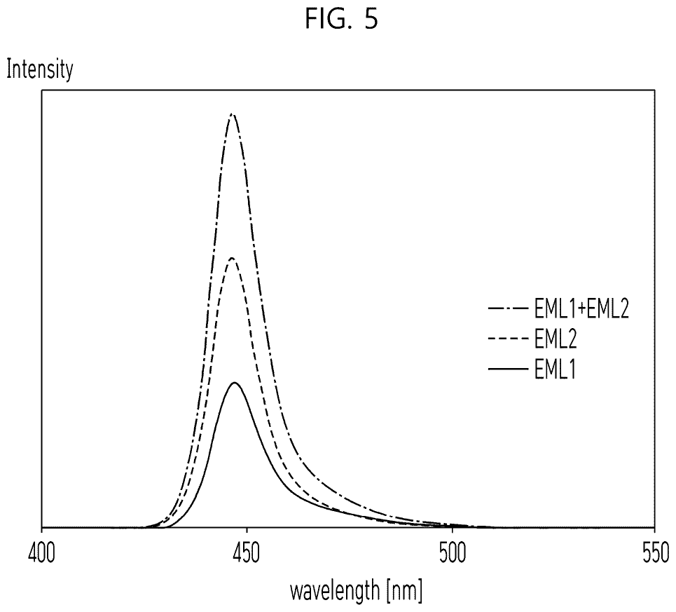

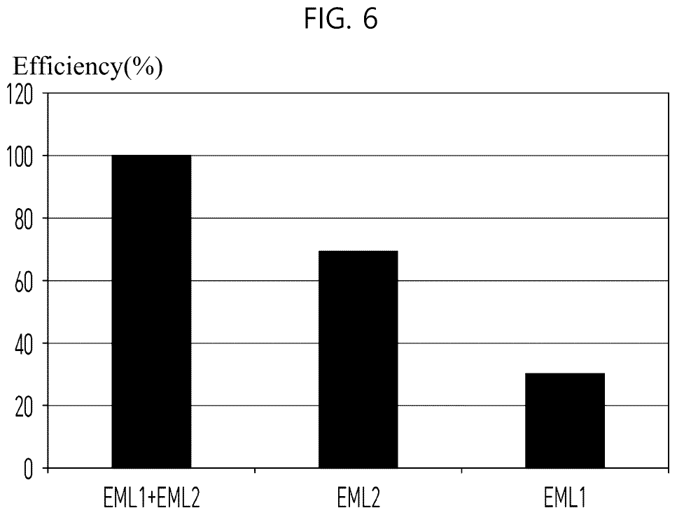

FIG. 4 is a schematic diagram comparatively showing efficiencies of the respective light emitting stacks of the light emitting device according to one or more embodiments of the present disclosure. FIG. 5 is a graph showing intensity influences of the respective light emitting layers of FIG. 4. FIG. 6 is a graph showing efficiency influences of the respective light emitting layers of FIG. 4.

As shown in FIGS. 4 to 6, in a tandem light emitting device which emits light in the top emission manner, the first and second light emitting layers 235 and 253 overlap each other. Light emitted from the first and second light emitting layers 235 and 253 are radiated in both the upper and lower directions, resonates between the anode 220 and the cathode 275, and is finally transmitted through the transflective cathode 275.

Here, among light passing through the cathode 275, the efficiency ratio of light emitted from the first light emitting layer 235 located on the lower side is 30% and the efficiency ratio of light emitted from the second light emitting layer 253 located on the upper side is 70%, and this means that the second light emitting layer 253 makes a relatively significant contribution to light emission in the light emitting device.

In terms of the structure of the light emitting device, the second light emitting layer 253 located on the upper side may emit light with greater efficiency than the first light emitting layer 235 located on the lower side, and this means that the second light emitting layer 253 makes a relatively significant contribution to light emission in the light emitting device.

In terms of the structure of the light emitting device, the second light emitting layer 253 close to the cathode 275, from which light exit, can emit light with greater efficiency than other light emitting layers in a structure including a plurality of stacks. Further, this means that the second light emitting layer 253, has an influence on efficiency more sensitively than the first light emitting layer 235.

The light emitting device and the light emitting display device according to one or more embodiments of the present disclosure, considering that an inflection section occurs in the same color coordinates when the content of the dopant included in the second light emitting layer is a certain level or more in at least the blue light emitting device according to the light emission principle of Table 1 and FIGS. 4 to 6, can reduce sensitivity to occurrence of an inflection section by lowering the content of the dopant in the second light emitting layer 253 in the second stack S2 than the content of the dopant in the first light emitting layer 235 in the first stack S1 of the blue light emitting layer. Alternatively, as another example, sensitivity to occurrence of the inflection section can be reduced by using a material with a shorter PL peak wavelength as the dopant used in the second light emitting layer 253 in the second stack S2 which has a great influence on efficiency.

As shown in FIG. 1, at least one of the first light emitting layer 235 or the second light emitting layer 253 can be divided into the first and second sub-light emitting layers EMLx1 and EMLx2, which are in contact with each other, and the first and second sub-light emitting layers EMLx1 and EMLx2 can be formed of different materials as the host or the dopant, thereby being capable of reducing sensitivity to occurrence of the inflection section.

Hereinafter, the efficiencies and color coordinate characteristics of each of a blue light emitting device, a green light emitting device, and a red light emitting device will be examined by changing the dopant content of the first light emitting layer or the second light emitting layer of the structure of FIG. 1 in each light emitting device.

TABLE 2

| | | Comparison | | | | | | |
|---|---|---|---|---|---|---|---|---|
| | | between | | | | | | |
| | | average doping | | | | | | |
| | | amounts in | Dopant content of | | Dopant content of | | Blue light | |
| | | EML1 and | EML1 (vol %) | | EML2 (vol %) | | characteristics | |
| | | EML2(BH + BD) | EML11 | EML12 | EML21 | EML22 | CIEy | Cd/A |
| 4 | EXA1 | EML1 = EML2 | 2 | | 2 | | 0.057 | 10.50 |
| 5 | EXA2 | EML1 = EML2 | 2 | 2 | 2 | 2 | 0.057 | 12.01 |
| 6 | EXA3 | EML1 > EML2 | 3 | 2 | 2 | 2 | 0.057 | 12.03 |
| 7 | EXA4 | EML1 > EML2 | 2 | 3 | 2 | 2 | 0.057 | 12.24 |
| 8 | EXA5 | EML1 > EML2 | 3 | 2 | 2 | | 0.057 | 11.74 |
| 9 | EXA6 | EML1 > EML2 | 2 | 3 | 2 | | 0.057 | 11.83 |
| 10 | EXA7 | EML1 < EML2 | 2 | 2 | 3 | 2 | 0.057 | 11.92 |
| 11 | EXA8 | EML < EML2 | 2 | 2 | 2 | 3 | 0.057 | 11.96 |

| | | | | | | | |
|---|---|---|---|---|---|---|---|
| 12 | EXA9 | EML1 < EML2 | 2 | 3 | 2 | 0.057 | 11.39 |
| 13 | EXA10 | EML1 < EML2 | 2 | 2 | 3 | 0.057 | 11.75 |

In the test of Table 2, Example 4 EXA1 had the structure of FIG. 1, each of the first and second light emitting layers 235 and 253 was a single light emitting layer, and the first and second light emitting layers 235 and 253 used the same blue host BH1 and the same blue dopant BD1 to emit blue light. In Example 4 EXA1, the contents of the blue dopant in the first and second light emitting layers 235 and 253 were all set to 2 vol %. Each of the first light emitting layer 235 and the second light emitting layer 253 had a thickness of 200 Å.

For example, the blue host BH1 can use an anthracene compound, a pyrene compound, or the like, and the blue dopant BD1 can use a boron compound. The embodiments of the present disclosure are not limited to the listed materials of Examples as the blue host and the blue dopant.

In the test of Table 2, Example 5 EXA2 had the structure of FIG. 1, and each of the first and second light emitting layers 235 and 253 was formed by stacking first and second sub-light emitting layers EML11/EML12 or EML21/EML22. In addition, the first sub-light emitting layer EMLx1 of each of the first and second light emitting layers 235 and 253 used a first blue host BH1 and a first blue dopant BD1, and the second sub-light emitting layer EMLx2 used a second blue host BH2 and a second blue dopant BD2. The first and second blue hosts BH1 and BH2 can employ compounds of the same base, the HOMO energy level of the second blue host BH2 can be higher than or equal to the HOMO energy level of the first blue host BH1, and the LUMO energy level of the second blue host BH2 can be higher than or equal to the LUMO energy level of the first blue host BH1. Further, the first and second blue dopants BD1 and BD2 can employ compounds of the same base, and a difference between photoluminescence (PL) peak wavelengths of the two materials as the first and second blue dopants BD1 and BD2 can be 10 nm or less. The difference between the PL peak wavelengths of the first and second blue dopants BD1 and BD2 is preferably 5 nm or less, more preferably 3 nm or less. Further, the PL peak wavelength of the first blue dopant BD1 can be longer than the PL peak wavelength of the second blue dopant BD2. The thickness of each of the first sub-light emitting layers EML11 and EML21 and the second sub-light emitting layers EML12 and EML22 was set to 100 Å. In Example 5 EXA2, the contents of the blue dopants BD1 and BD2 in the first sub-light emitting layers EML11 and EML21 and the second sub-light emitting layers EML12 and EML22 of the first and second light emitting layers 235 and 253 were all set to 2 vol %. In some cases, the first and second blue dopants BD1 and BD2 can be the same, but only the dopant contents can be different.

In the same manner as in Example 5 EXA2, in Example 6 EXA3, Example 7 EXA4, Example 10 EXA7, and Example 11 EXA8, the first sub-light emitting layer EMLx1 of each of the first and second light emitting layers 235 and 253 used the first blue host BH1 and the first blue dopant BD1, and the second sub-light emitting layer EMLx2 used the second blue host BH2 and the second blue dopant BD2. Further, the thickness of each of the first sub-light emitting layers EML11 and EML21 and the second sub-light emitting layers EML12 and EML22 was set to 100 Å. In Example 6 EXA3 and Example 7 EXA4, each of the first and second light emitting layers 235 and 253 was formed by stacking first and second sub-light emitting layers EML11/EML12 or EML21/EML22

In Examples 6 to 9 EXA3, EXA4, EXA5, and EXA6, the average dopant content of the first light emitting layer 235 was set to be greater than the average dopant content of the second light emitting layer 253, in Example 6 EXA3, the dopant content of the first sub-light emitting layer EML11 of the first light emitting layer 235 was set to 3 vol %, and in Example 7 EXA4, the dopant content of the second sub-light emitting layer EML12 of the first light emitting layer 235 was set to 3 vol %. In Example 6 EXA3 and Example 7 EXA4, the dopant contents of the remaining sub-light emitting layers were set to 2 vol %. In Example 8 EXA5 and Example 9 EXA6, the first light emitting layer 235 was formed by stacking first and second sub-light emitting layers EML11/EML12, and the second light emitting layer 253 was formed as a single layer and included the blue host BH1 and the blue dopant BD1.

In Example 8 EXA5, the dopant content of the first sub-light emitting layer EML11 of the first light emitting layer 235 was set to 3 vol %, and in Example 9 EXA6, the dopant content of the second sub-light emitting layer EML12 of the first light emitting layer 235 was set to 3 vol %. The first sub-light emitting layer EML11 of the first light emitting layer 235 used the first blue host BH1 and the first blue dopant BD1, and the second sub-light emitting layer EML12 used the second blue host BH2 and the second blue dopant BD2. In these Examples, the second light emitting layer 253 was formed as a single layer and included the blue host BH1 and the blue dopant BD1, and the dopant content was set to 2 vol %.

In Examples 10 to 13 EXA7, EXA8, EXA9, and EXA10, the average dopant content of the second light emitting layer 253 was set to be greater than the average dopant content of the first light emitting layer 235. In Example 10 EXA7 and Example 11 EXA8, each of the first and second light emitting layers 235 and 253 was formed by stacking first and second sub-light emitting layers EML11/EML12 or EML21/EML22. In Example 10 EXA7, the dopant content of the first sub-light emitting layer EML21 of the second light emitting layer 253 was set to 3 vol %, and in Example 11 EXA8, the dopant content of the second sub-light emitting layer EML22 of the second light emitting layer 253 was set to 3 vol %. In Example 10 EXA7 and Example 11 EXA8, the dopant contents of the remaining sub-light emitting layers were set to 2 vol %. The first sub-light emitting layers EML11 and EML21 of the first and second light emitting layers 235 and 253 used the first blue host BH1 and the first blue dopant BD1, and the second sub-light emitting layers EML12 and EML22 used the second blue host BH2 and the second blue dopant BD2.

In Example 12 EXA9 and Example 13 EXA10, the first light emitting layer 235 was formed as a single layer, and the second light emitting layer 253 was formed by stacking first and second sub-light emitting layers EML21/EML22. In Example 12 EXA9, the dopant content of the first sub-light emitting layer EML21 of the second light emitting layer 253 was set to 3 vol %, and in Example 13 EXA10, the dopant content of the second sub-light emitting layer EML22 of the second light emitting layer 253 was set to 3 vol %. In these Examples, the first light emitting layer 235 was formed as a single layer and included the blue host BH1 and the blue dopant BD1, and the dopant content was set to 2 vol %.

Depending on the results in Table 2, in comparison between Example 4 EXA1 and Examples 5 to 13 EXA2 to EXA10, it can be seen that the case in which multiple divided sub-light emitting layers are applied exhibits increased efficiency compared to the case in which a single light emitting layer is applied to each stack. Further, as in Example 5 EXA2 to Example 13 EXA10, it can be seen that efficiency is improved when multiple divided sub-light emitting layers is applied to any one of the first and second light emitting layers 235 and 253, compared to Example 4 EXA1 in which a single light emitting layer is applied to each stack.

In addition, looking at Example 5 EXA2, Example 6 EXA3, Example 7 EXA4, Example 10 EXA7, and Example 11 EXA8, it can be seen that the efficiency improvement effect is great when both the first and second light emitting layers 235 and 253 are provided in a multiple sub-light emitting layer structure or when the average dopant content of the first light emitting layer 235 is greater than the average dopant content of the second light emitting layer 253.

Further, in comparison among Examples 6 to 9 EXA3, EXA4, EXA5, and EXA6, it can be seen that efficiency is improved when the dopant content of the second sub-light emitting layer EML12 close to the cathode among the multiple sub-light emitting layers in the first light emitting layer 235 is high.

Likewise, in comparison among Examples 10 to 13 EXA7, EXA8, EXA9, and EXA10, it can be seen that efficiency is improved when the dopant content of the second sub-light emitting layer EML22 close to the cathode among the multiple sub-light emitting layers in the second light emitting layer 253 is high.

Consequently, referring to Tables 1 and 2, in order to increase the efficiency effect in the blue light emitting device within a range that does not cause an inflection section, the average dopant content of the first light emitting layer closer to the anode must be increased and, as set forth in the results of Table 2, it can be seen that, if multiple sub-light emitting layers are applied to the light emitting layer in each light emitting stack in the blue light emitting device, efficiency is improved when the dopant content of the second sub-light emitting layer close to the cathode is high.

Hereinafter, test results obtained by varying the dopant contents when multiple sub-light emitting layers are applied to a plurality of light emitting layers in the green light emitting device are examined.

TABLE 3

| | | Comparison | | | | | | |
|---|---|---|---|---|---|---|---|---|
| | | between | | | | | | |
| | | average doping | | | | | | |
| | | amounts in | Dopant content of | | Dopant content of | | Green light | |
| | | EML1 and | EML1 (vol %) | | EML2 (vol %) | | characteristics | |
| | | EML2 (GH + GD) | EML11 | EML12 | EML21 | EML22 | CIEx | Cd/A |
| 14 | EXB1 | EML1 = EML2 | 8 | | 8 | | 0.248 | 273.3 |
| 15 | EXB2 | EML1 = EML2 | 8 | 8 | 8 | 8 | 0.248 | 284.3 |
| 16 | EXB3 | EML1 > EML2 | 10 | 8 | 8 | 8 | 0.248 | 281.4 |
| 17 | EXB4 | EML1 > EML2 | 8 | 10 | 8 | 8 | 0.248 | 283.3 |
| 18 | EXB5 | EML1 > EML2 | 10 | 8 | 8 | | 0.248 | 268.0 |
| 19 | EXB6 | EML1 > EML2 | 8 | 10 | 8 | | 0.248 | 269.9 |
| 20 | EXB7 | EML1 < EML2 | 8 | 8 | 10 | 8 | 0.248 | 284.3 |
| 21 | EXB8 | EML < EML2 | 8 | 8 | 8 | 10 | 0.248 | 285.1 |

| | | | | | | | |
|---|---|---|---|---|---|---|---|
| 22 | EXB9 | EML1 < EML2 | 8 | 10 | 8 | 0.248 | 264.9 |
| 23 | EXB10 | EML1 < EML2 | 8 | 8 | 10 | 0.248 | 270.4 |

In the test of Table 3, Example 14 EXB1 had the structure of FIG. 1, each of the first and second light emitting layers 235 and 253 was a single light emitting layer, and the first and second light emitting layers 235 and 253 used the same green host GH1 and the same green dopant GD1 to emit green light. In Example 14 EXB1, the contents of the green dopant in the first and second light emitting layers 235 and 253 were all set to 8 vol %. Each of the first light emitting layer 235 and the second light emitting layer 253 had a thickness of 200 Å.

The green host GH1 can include, for example, a host material including an aryl-carbazoyl group or carbazoyl-alkylene group compound, CBP, or mCP. The green dopant GD1 can include, for example, an Ir complex including Ir(ppy)3(fac tris(2-phenylpyridine)iridium). The embodiments of the present disclosure are not limited to the listed materials of Examples as the green host and the green dopant.

In the test of Table 3, Example 15 EXB2 had the structure of FIG. 1, and each of the first and second light emitting layers 235 and 253 was formed by stacking first and second sub-light emitting layers EML11/EML12 or EML21/EML22. In addition, the first sub-light emitting layer EMLx1 of each of the first and second light emitting layers 235 and 253 used a first green host GH1 and a first green dopant GD1, and the second sub-light emitting layer EMLx2 used a second green host GH2 and a second green dopant GD2. The first and second green hosts GH1 and GH2 can employ compounds of the same base, the HOMO energy level of the second green host GH2 can be higher than or equal to the HOMO energy level of the first green green host GH1, and the LUMO energy level of the second green host GH2 can be higher than or equal to the LUMO energy level of the first green host GH1. Further, the first and second green dopants GD1 and GD2 can employ compounds of the same base, and a difference between photoluminescence (PL) peak wavelengths of the two materials as the first and second green dopants GD1 and GD2 can be 10 nm or less. The difference between the PL peak wavelengths of the first and second green dopants GD1 and GD2 is preferably 5 nm or less, more preferably 3 nm or less. Further, the PL peak wavelength of the first green dopant GD1 can be longer than the PL peak wavelength of the second green dopant GD2. The thickness of each of the first sub-light emitting layers EML11 and EML21 and the second sub-light emitting layers EML12 and EML22 was set to 100 Å. In Example 15 EXB2, each of the first and second light emitting layers 235 and 253 was formed by stacking first and second sub-light emitting layers EML11/EML12 or EML21/EML22. In Example 15 EXB2, the contents of the green dopants GD1 and GD2 in the first sub-light emitting layers EML11 and EML21 and the second sub-light emitting layers EML12 and EML22 of the first and second light emitting layers 235 and 253 were all set to 8 vol %. In some cases, the first and second green dopants GD1 and GD2 can be the same, but only the dopant contents can be different.

In Example 15 EXB2, in Example 16 EXB3, Example 17 EXB4, Example 20 EXB7, and Example 21 EXB8, each of the first and second light emitting layers 235 and 253 was formed by stacking first and second sub-light emitting layers EML11/EML12 or EML21/EML22. In the same manner as in Example 15 EXB2, in Example 16 EXB3, Example 17 EXB4, Example 20 EXB7, and Example 21 EXB8, the first sub-light emitting layer EMLx1 of each of the first and second light emitting layers 235 and 253 used the first green host GH1 and the first green dopant GD1, and the second sub-light emitting layer EMLx2 used the second green host GH2 and the second green dopant GD2. Further, the thickness of each of the first sub-light emitting layers EML11 and EML21 and the second sub-light emitting layers EML12 and EML22 was set to 100 Å.

In Example 18 EXB5, the first light emitting layer 235 was formed by stacking first and second sub-light emitting layers EML11/EML12, and the second light emitting layer 253 was formed as a single layer. In Examples 16 to 19 EXB3, EXB4, EXB5, and EXB6, the average dopant content of the first light emitting layer 235 was set to be greater than the average dopant content of the second light emitting layer 253, in Example 16 EXB3, the dopant content of the first sub-light emitting layer EML11 of the first light emitting layer 235 was set to 10 vol %, and in Example 17 EXB4, the dopant content of the second sub-light emitting layer EML12 of the first light emitting layer 235 was set to 10 vol %. In Example 16 EXB3 and Example 17 EXB4, the dopant contents of the remaining sub-light emitting layers were set to 8 vol %.

In Example 22 EXB9, the first light emitting layer 235 was formed as a single layer, and the second light emitting layer 253 was formed by stacking first and second sub-light emitting layers EML21/EML22. In Example 18 EXB5, the dopant content of the first sub-light emitting layer EML11 of the first light emitting layer 235 was set to 10 vol %, and in Example 19 EXB6, the dopant content of the second sub-light emitting layer EML12 of the first light emitting layer 235 was set to 10 vol %. The first sub-light emitting layer EML11 of the first light emitting layer 235 used the first green host GH1 and the first green dopant GD1, and the second sub-light emitting layer EML12 used the second green host GH2 and the second green dopant GD2. In these Examples, the second light emitting layer 253 was formed as a single layer and included the green host GH1 and the green dopant GD1, and the dopant content was set to 8 vol %.

In Examples 20 to 23 EXB7, EXB8, EXB9, and EXB10, the average dopant content of the second light emitting layer 253 was set to be greater than the average dopant content of the first light emitting layer 235. In Example 20 EXB7, the dopant content of the first sub-light emitting layer EML21 of the second light emitting layer 253 was set to 10 vol %, and in Example 21 EXB8, the dopant content of the second sub-light emitting layer EML22 of the second light emitting layer 253 was set to 10 vol %. In Example 20 EXB7 and Example 21 EXB8, the dopant contents of the remaining sub-light emitting layers were set to 8 vol %. The first sub-light emitting layers EML11 and EML21 of the first and second light emitting layers 235 and 253 used the first green host GH1 and the first green dopant GD1, and the second sub-light emitting layers EML12 and EML22 used the second green host GH2 and the second green dopant GD2.

In Example 22 EXB9, the dopant content of the first sub-light emitting layer EML21 of the second light emitting layer 253 was set to 10 vol %, and in Example 23 EXB10, the dopant content of the second sub-light emitting layer EML22 of the second light emitting layer 253 was set to 10 vol %. In these Examples, the first light emitting layer 235 was formed as a single layer and included the green host GH1 and the green dopant GD1, and the dopant content was set to 8 vol %.

Depending on the results in Table 3, it can be seen that efficiency increases in Example 15 EXB2, Example 16 EXB3, Example 17 EXB4, Example 20 EXB7, and Example 21 EXB8 in which the multiple sub-light emitting layers are provided in all stacks, compared to Example 14 EXB1, Example 18 EXB5, Example 19 EXB6, Example 22 EXB9, and Example 23 EXB10 in which the single light emitting layer is provided in any stack. For example, it can be seen that, in the case of the green light emitting device, efficiency is improved when the multiple sub-light emitting layers are provided in each stack compared to the structure having the single layer in any one stack.

Further, in comparison between Examples 20 to 23 EXB7, EXB8, EXB9, and EXB10 and Examples 16 to 19 EXB3, EXB4, EXB5, and EXB6, it can be seen that the efficiency improvement effect is great when the average dopant content of the second light emitting layer 253 is greater than the average dopant content of the first light emitting layer 235.

In comparison among Examples 16 to 19 EXB3, EXB4, EXB5, and EXB6, it can be conformed that efficiency is improved when the dopant content of the second sub-light emitting layer EML12 close to the cathode among the multiple sub-light emitting layers in the first light emitting layer 235 is high.

Likewise, in comparison among Examples 20 to 23 EXB7, EXB8, EXB9, and EXB10, it can be conformed that efficiency is improved when the dopant content of the second sub-light emitting layer EML22 close to the cathode among the multiple sub-light emitting layers in the second light emitting layer 253 is high.

Consequently, referring to Table 3, in order to increase the efficiency effect in the green light emitting device while being not sensitive to occurrence of an inflection section, the average dopant content of the second light emitting layer can be higher than or equal to the average dopant content of the first light emitting layer.

In addition, it can be seen that the efficiency of the green light emitting device is increased by applying the multiple sub-light emitting layer structure to both the first and second light emitting layers, and, if multiple sub-light emitting layers are applied to the light emitting layer in each light emitting stack or applied to the light emitting layer in any one light emitting stack, the efficiency is improved when the dopant content of the second sub-light emitting layer close to the cathode is high.

Hereinafter, test results obtained by varying the dopant contents when multiple sub-light emitting layers are applied to a plurality of light emitting layers in the red light emitting device are examined.

TABLE 4

| | | Comparison | | | | | | |
|---|---|---|---|---|---|---|---|---|
| | | between | | | | | | |
| | | average doping | | | | | | |
| | | amount of | Dopant amount in | | Dopant amount in | | Red light | |
| | | EML1 and | EML1 (vol %) | | EML2 (vol %) | | characteristics | |
| | | EML2(RH + RD) | EML11 | EML12 | EML21 | EML22 | CIEx | Cd/A |
| 24 | EXC1 | EML1 = EML2 | 3 | | 3 | | 0.685 | 112.0 |
| 25 | EXC2 | EML1 = EML2 | 3 | 3 | 3 | 3 | 0.685 | 115.4 |
| 26 | EXC3 | EML1 > EML2 | 4 | 3 | 3 | 3 | 0.685 | 111.9 |
| 27 | EXC4 | EML1 > EML2 | 3 | 4 | 3 | 3 | 0.685 | 112.8 |
| 28 | EXC5 | EML1 > EML2 | 4 | 3 | 3 | | 0.685 | 109.9 |
| 29 | EXC6 | EML1 > EML2 | 3 | 4 | 3 | | 0.685 | 110.1 |
| 30 | EXC7 | EML1 < EML2 | 3 | 3 | 4 | 3 | 0.685 | 116.2 |
| 31 | EXC8 | EML < EML2 | 3 | 3 | 3 | 4 | 0.685 | 116.7 |

| | | | | | | | |
|---|---|---|---|---|---|---|---|
| 32 | EXC9 | EML1 < EML2 | 3 | 4 | 3 | 0.685 | 110.8 |
| 33 | EXC10 | EML1 < EML2 | 3 | 3 | 4 | 0.685 | 112.1 |

In the test of Table 4, Example 24 EXC1 had the structure of FIG. 1, each of the first and second light emitting layers 235 and 253 was a single light emitting layer, and the first and second light emitting layers 235 and 253 used the same red host RH1 and the same red dopant RD1 to emit red light. In Example 24 EXC1, the contents of the red dopant in the first and second light emitting layers 235 and 253 were all set to 3 vol %. Each of the first light emitting layer 235 and the second light emitting layer 253 had a thickness of 200 Å.

The red host RH1 can include, for example, a carbazole compound including an aromatic group substance, such as phenyl, naphthyl, biphenyl, terphenyl, or phenanthrenyl, or a heterocyclic group substance, such as pyridinyl, bipyridinyl, quinolinyl, isoquinolinyl, quinoxalinyl, terpyridinyl, or phenanthrolinyl. The red dopant RD1 can include, for example, an iridium (Ir) complex including bis(1-phenylquinoline) acetylacetonate iridium (PQIr(acac)), tris(1-phenylquinoline)iridium (PQIr), or octaethylporphyrin platinum (PtOEP). The embodiments of the present disclosure are not limited to the listed materials of Examples as the red host and the red dopant.

In the test of Table 4, Example 25 EXC2 had the structure of FIG. 1, and each of the first and second light emitting layers 235 and 253 was formed by stacking first and second sub-light emitting layers EML11/EML12 or EML21/EML22. In addition, the first sub-light emitting layer EMLx1 of each of the first and second light emitting layers 235 and 253 used a first red host RH1 and a first red dopant RD1, and the second sub-light emitting layer EMLx2 used a second red host RH2 and a second green dopant RD2. The first and second red hosts RH1 and RH2 can employ compounds of the same base, the HOMO energy level of the second red host RH2 can be higher than or equal to the HOMO energy level of the first red host RH1, and the LUMO energy level of the second red host RH2 can be higher than or equal to the LUMO energy level of the first red host RH1. Further, the first and second red dopants RD1 and RD2 can employ compounds of the same base, and a difference between photoluminescence (PL) peak wavelengths of the two materials as the first and second red dopants RD1 and RD2 can be 10 nm or less. The difference between the PL peak wavelengths of the first and second red dopants RD1 and RD2 is preferably 5 nm or less, more preferably 3 nm or less. Further, the PL peak wavelength of the first red dopant RD1 can be longer than the PL peak wavelength of the second red dopant RD2. The thickness of each of the first sub-light emitting layers EML11 and EML21 and the second sub-light emitting layers EML12 and EML22 was set to 100 Å. In Example 25 EXC5, the contents of the red dopants RD1 and RD2 in the first sub-light emitting layers EML11 and EML21 and the second sub-light emitting layers EML12 and EML22 of the first and second light emitting layers 235 and 253 were all set to 3 vol %. In some cases, the first and second red dopants RD1 and RD2 can be the same, but only the dopant contents can be different.

In Example 25 EXC2, in Example 26 EXC3, Example 27 EXC4, Example 30 EXC7, each of the first and second light emitting layers 235 and 253 was formed by stacking first and second sub-light emitting layers EML11/EML12 or EML21/EML22. In the same manner as in Example 25 EXC2, in Example 26 EXC3, Example 27 EXC4, Example 30 EXC7, and Example 31 EXC8, the first sub-light emitting layer EMLx1 of each of the first and second light emitting layers 235 and 253 used the first red host RH1 and the first red dopant RD1, and the second sub-light emitting layer EMLx2 used the second red host RH2 and the second red dopant RD2. Further, the thickness of each of the first sub-light emitting layers EML11 and EML21 and the second sub-light emitting layers EML12 and EML22 was set to 100 Å.

In Examples 26 to 29 EXC3, EXC4, EXC5, and EXC6, the average dopant content of the first light emitting layer 235 was set to be greater than the average dopant content of the second light emitting layer 253, in Example 26 EXC3, the dopant content of the first sub-light emitting layer EML11 of the first light emitting layer 235 was set to 4 vol %, and in Example 27 EXC4, the dopant content of the second sub-light emitting layer EML12 of the first light emitting layer 235 was set to 4 vol %. In Example 26 EXC3 and Example 27 EXC4, the dopant contents of the remaining sub-light emitting layers were set to 3 vol %.

In Example 28 EXC5 and Example 29 EXC6, the first light emitting layer 235 was formed by stacking first and second sub-light emitting layers EML11/EML12, and the second light emitting layer 253 was formed as a single layer. In Example 28 EXC5, the dopant content of the first sub-light emitting layer EML11 of the first light emitting layer 235 was set to 4 vol %, and in Example 29 EXC6, the dopant content of the second sub-light emitting layer EML12 of the first light emitting layer 235 was set to 4 vol %. The first sub-light emitting layer EML11 of the first light emitting layer 235 used the first red host RH1 and the first red dopant RD1, and the second sub-light emitting layer EML12 used the second red host RH2 and the second red dopant RD2. In these Examples, the second light emitting layer 253 was formed as a single layer and included the red host RH1 and the red dopant RD1, and the dopant content was set to 3 vol %.

In Examples 30 to 33 EXC7, EXC8, EXC9, and EXC10, the average dopant content of the second light emitting layer 253 was set to be greater than the average dopant content of the first light emitting layer 235. In Example 30 EXC7, the dopant content of the first sub-light emitting layer EML21 of the second light emitting layer 253 was set to 4 vol %, and in Example 31 EXC8, the dopant content of the second sub-light emitting layer EML22 of the second light emitting layer 253 was set to 4 vol %. In Example 30 EXC7 and Example 31 EXC8, the dopant contents of the remaining sub-light emitting layers were set to 3 vol %. The first sub-light emitting layers EML11 and EML21 of the first and second light emitting layers 235 and 253 used the first red host RH1 and the first red dopant RD1, and the second sub-light emitting layers EML12 and EML22 used the second red host RH2 and the second red dopant RD2.

In Example 32 EXC9 and Example 33 EXC10, the first light emitting layer 235 was formed as a single layer, and the second light emitting layer 253 was formed by stacking first and second sub-light emitting layers EML21/EML22. In Example 32 EXC9, the dopant content of the first sub-light emitting layer EML21 of the second light emitting layer 253 was set to 4 vol %, and in Example 33 EXC10, the dopant content of the second sub-light emitting layer EML22 of the second light emitting layer 253 was set to 4 vol %. In these Examples, the first light emitting layer 235 was formed as a single layer and included the red host RH1 and the red dopant RD1, and the dopant content was set to 3 vol %.

Depending on the results in Table 4, efficiency increases in Example 25 EXC2, Example 27 EXC4, Example 30 EXC7, and Example 31 EXC8 in which the multiple sub-light emitting layers are provided in all stacks.

In the case of the red light emitting device, efficiency is improved when the multiple sub-light emitting layers are applied to any one of the first light emitting layer 235 and the second light emitting layer 253. The efficiency can be further improved in Example 27 EXC4, Example 30 EXC7, and Example 31 EXC8 in which both the first and second light emitting layers 235 and 253 include the multiple sub-light emitting layers compared to Example 28 EXC5, Example 29 EXC6, Example 32 EXC9, and Example 33 EXC10 in which one of the first and second light emitting layers 235 and 253 includes the multiple sub-light emitting layers.

Further, in comparison between Examples 30 to 333 EXC7, EXC8, EXC9, and EXC10 and Examples 26 to 29 EXC3, EXC4, EXC5, and EXC6, it can be seen that the efficiency improvement effect is great when the average dopant content of the second light emitting layer 253 is greater than the average dopant content of the first light emitting layer 235.

In comparison among Examples 26 to 29 EXC3, EXC4, EXC5, and EXC6, it can be conformed that efficiency is improved when the dopant content of the second sub-light emitting layer EML12 close to the cathode among the multiple sub-light emitting layers in the first light emitting layer 235 is high.

Likewise, in comparison among Examples 30 to 33 EXC7, EXC8, EXC9, and EXC10, it can be conformed that efficiency is improved when the dopant content of the second sub-light emitting layer EML22 close to the cathode among the multiple sub-light emitting layers in the second light emitting layer 253 is high.

Consequently, referring to Table 4, in order to increase the efficiency effect in the red light emitting device while being not sensitive to occurrence of an inflection section, the average dopant content of the second light emitting layer can be higher than or equal to the average dopant content of the first light emitting layer.

In addition, it can be seen that the efficiency of the red light emitting device is increased by applying the multiple sub-light emitting layer structure to both the first and second light emitting layers, and, if multiple sub-light emitting layers are applied to the light emitting layer in each light emitting stack or applied to the light emitting layer in any one light emitting stack, the efficiency is improved when the dopant content of the second sub-light emitting layer close to the cathode is high.

The physical properties of the hosts and dopants included in the multiple sub-light emitting layers in the light emitting device according to one or more embodiments of the present disclosure are set forth in Tables 5 to 7.

TABLE 5

| Blue host (BH) | | Blue dopant (BD) | | |
|---|---|---|---|---|
| LUMO(eV) | HOMO(eV) | LUMO(eV) | HOMO(eV) | PL peak (nm) |
| −3.2~−2.3 | −6.2~−5.4 | −2.8~−2.0 | −5.6~−5.0 | 445~465 |

TABLE 6

| Green host (GH) | | Green dopant (GD) | | |
|---|---|---|---|---|
| LUMO(eV) | HOMO(eV) | LUMO(eV) | HOMO(eV) | PL peak (nm) |
| −3.5~−1.8 | −5.5~−5.0 | −2.8~−2.3 | −5.3~−4.9 | 510~530 |

TABLE 7

| Red host (RH) | | Red dopant (RD) | | |
|---|---|---|---|---|
| LUMO(eV) | HOMO(eV) | LUMO(eV) | HOMO(eV) | PL peak (nm) |
| −3.3~−2.5 | −5.8~−5.1 | −3.3~−2.9 | −5.5~−4.9 | 600~635 |

Hereinafter, various feasible examples of adjacent first and second sub-light emitting layers in one or more embodiments of the present disclosure will be described.

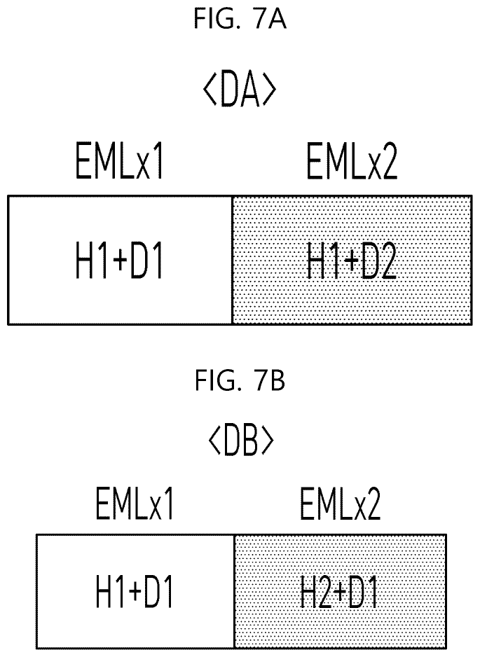

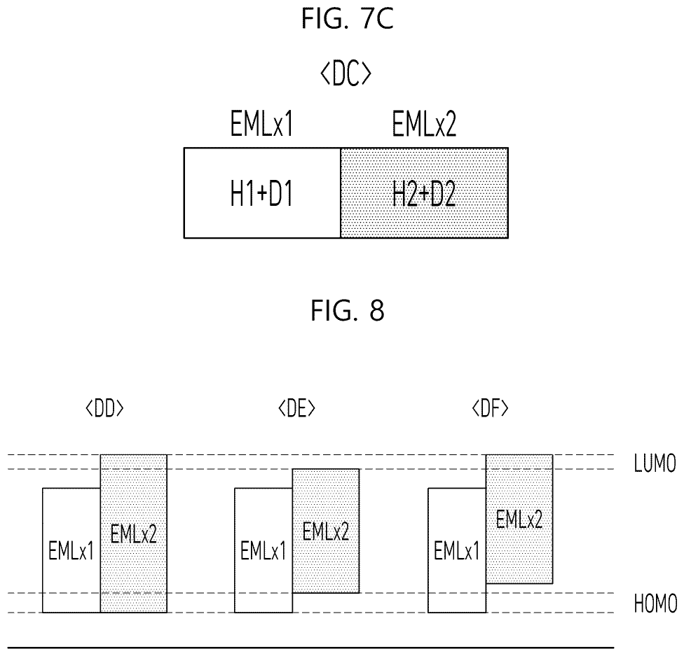

FIG. 7A to 7C show embodiments of the present disclosure in which one light emitting layer of the light emitting device of the present disclosure includes a plurality of sub-light emitting layers. FIG. 8 shows embodiments in which, if the light emitting layer of the light emitting device of the present disclosure includes a plurality of sub-light emitting layers, hosts of adjacent sub-light emitting layers are different.

In a first embodiment DA of the present disclosure as shown in FIG. 7A, the light emitting layer of one of the light emitting stacks can include a first sub-light emitting layer EMLx1 including a first host H1 and a first dopant D1, and a second sub-light emitting layer EMLx2 including the first host H1 and a second dopant D2. In the first embodiment DA, this means that the first host H1 includes one or more host materials in the first and second sub-light emitting layers EMLx1 and EMLx2, but uses the same materials in the first and second sub-light emitting layers EMLx1 and EMLx2. Therefore, the first host H1 can be a single kind of host material or can include a plurality of different kinds of host materials. Further, in the first embodiment DA, the first dopant D1 and the second dopant D2 are different, and in the first and second sub-light emitting layers EMLx1 and EMLx2, only dopant materials are different. Here, when the dopants D1 and D2 are different, the PL peak wavelength of the second dopant D2 applied to the second sub-light emitting layer EMLx2 is shorter than the PL peak wavelength of the first dopant D1 applied to the first sub-light emitting layer EMLx1 to achieve equal light emission from the first and second sub-light emitting layers EMLx1 and EMLx2. The reason for this is that, since the second sub-light emitting layer EMLx2 has a greater influence on efficiency increase than the first sub-emitting layer EMLx1, a dopant having a relatively short peak wavelength is included in the second sub-light emitting layer EMLx2 to obtain luminous efficacy similar to that of the first sub-light emitting layer EMLx1. Here, even if the first and second dopants D1 and D2 are different, a difference between the PL peak wavelengths of the first and second red dopants D1 and D2 is 10 nm or less so that the first and second sub-light emitting layers EMLx1 and EMLx2 reproduce emission colors of the same series. The difference between the PL peak wavelengths of the first and second dopants D1 and D2 is preferably 5 nm or less, more preferably 3 nm or less.

In a second embodiment DB of the present disclosure as shown in FIG. 7B, the light emitting layer of one of the light emitting stacks can include a first sub-light emitting layer EMLx1 including a first host H1 and a first dopant D1, and a second sub-light emitting layer EMLx2 including a second host H2 and the first dopant D1. In the second embodiment DB, this means a case in which each of the first host H1 and the second host H2 includes one or more host materials, and any one host material is different from each other. The second embodiment DB indicates a case in which the first and second sub-light emitting layers EMLx1 and EMLx2 use the same dopant D1, but include different kinds of hosts.

Here, among the first and second hosts H1 and H2, the second host H2 included in the second sub-light emitting layer EMLx2 has a LUMO energy level which is higher than or equal to that of the first host H1 included in the first sub-light emitting layer EMLx1, or a HOMO energy level which is higher than or equal to that of the first host H1 included in the first sub-light emitting layer EMLx1. This serves to enable independent light emission, when the first and second sub-light emitting layers EMLx1 and EMLx2 are provided. Holes from the hole transport layer 213 or 251 (in FIG. 1) adjacent to the first sub-light emitting layer EMLx1 and electrons from the electron transport layer 237 or 255 (in FIG. 1) adjacent to the second sub-light emitting layer EMLx2 are transferred to the area of the light emitting layer, and the first sub-light emitting layer EMLx1 can have a lower (deeper) HOMO energy level compared to the HOMO energy level of the second sub-light emitting layer EMLx2 so that holes do not directly pass to the second sub-light emitting layer EMLx2 and partially stay in the first sub-light emitting layer EMLx1 to contribute to light emission within the first sub-light emitting layer EMLx1. In addition, the second sub-light emitting layer EMLx2 can have a higher (shallower) LUMO energy level compared to the LUMO energy level of the first sub-light emitting layer EMLx2 so that electrons do not directly pass to the first sub-light emitting layer EMLx1 and partially stay in the second sub-light emitting layer EMLx1 to contribute to light emission within the second sub-light emitting layer EMLx2.

Here, a LUMO energy level difference between the first sub-light emitting layer EMLx1 and the second sub-light emitting layer EMLx2 can be 0.53 eV or less in the blue light emitting layer. Further, the LUMO energy level difference between the first sub-light emitting layer EMLx1 and the second sub-light emitting layer EMLx2 can be 1.55 eV or less in the green light emitting layer. In addition, the LUMO energy level difference between the first sub-light emitting layer EMLx1 and the second sub-light emitting layer EMLx2 can be 0.43 eV or less in the red light emitting layer.

A HOMO energy level difference between the first sub-light emitting layer EMLx1 and the second sub-light emitting layer EMLx2 can be 0.50 eV or less in the blue light emitting layer. Further, the HOMO energy level difference between the first sub-light emitting layer EMLx1 and the second sub-light emitting layer EMLx2 can be 0.10 eV or less in the green light emitting layer. In addition, the HOMO energy level difference between the first sub-light emitting layer EMLx1 and the second sub-light emitting layer EMLx2 can be 0.53 eV or less in the red light emitting layer.

In a third embodiment DC of the present disclosure as shown in FIG. 7C, the light emitting layer of one of the light emitting stacks can include a first sub-light emitting layer EMLx1 including a first host H1 and a first dopant D1, and a second sub-light emitting layer EMLx2 including a second host H2 and the second dopant D2. In the third embodiment DE, this means a case in which the hosts and the dopants in the first and second sub-light emitting layers EMLx1 and EMLx2 are different. A difference between the first and second dopants D1 and D2 in the third embodiment DC is as described in FIG. 7A, and a detailed description may be omitted or briefly given. A difference between the first and second hosts H1 and H2 in the third embodiment DC is as described in FIG. 7B.

FIG. 8 comparatively shows HOMO energy levels and LUMO energy levels of hosts in first and second sub-light emitting layers EMLx1 and EMLx2 in fourth to sixth embodiments DD, DE, and DF of the present disclosure as.

Referring to FIG. 8, the fourth embodiment DD shows an example in which the HOMO energy level of the host in the first sub-light emitting layer EMLx1 is equal to the HOMO energy level of the host in the second sub-light emitting layer EMLx2, and the LUMO energy level of the host in the second sub-light emitting layer EMLx2 is higher than the LUMO energy level of the host in the first sub-light emitting layer EMLx1.

The fifth embodiment DE shows an example in which the HOMO energy level of the host in the second sub-light emitting layer EMLx2 is higher than or equal to the HOMO energy level of the host in the first sub-light emitting layer EMLx1, and the LUMO energy level of the host in the second sub-light emitting layer EMLx2 is higher than or equal to the LUMO energy level of the host in the first sub-light emitting layer EMLx1. The fifth embodiment DE includes a case in which the first and second sub-light emitting layers EMLx1 and EMLx2 have the same energy band gap.

The sixth embodiment DF shows an example in which the HOMO energy level of the host in the second sub-light emitting layer EMLx2 is higher than the HOMO energy level of the host in the first sub-light emitting layer EMLx1, and the LUMO energy level of the host in the second sub-light emitting layer EMLx2 is higher than the LUMO energy level of the host in the first sub-light emitting layer EMLx1. The sixth embodiment DF includes a case in which the first and second sub-light emitting layers EMLx1 and EMLx2 have the same energy band gap.

As set forth in Tables 1 to 4 above, the blue light emitting device, the green light emitting device, and the red light emitting device have the maximum efficiency at different doping amounts of the dopants.

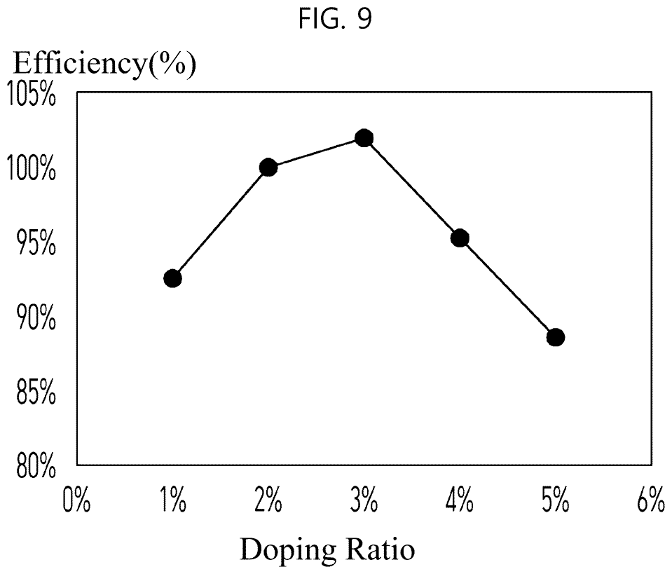

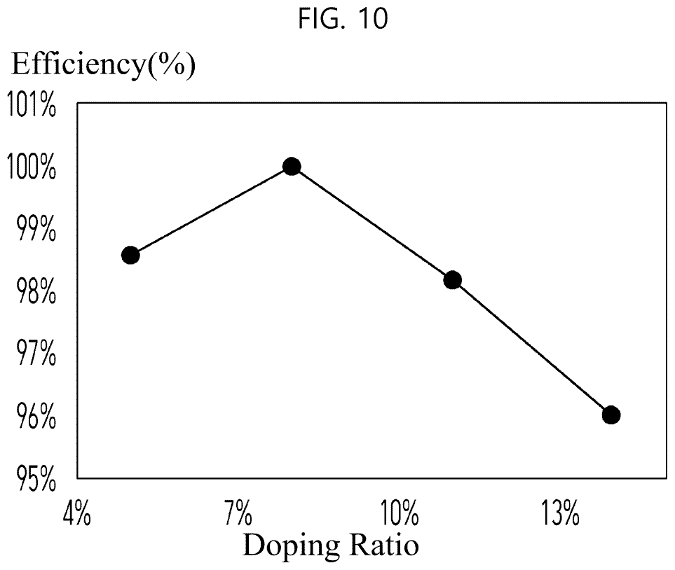

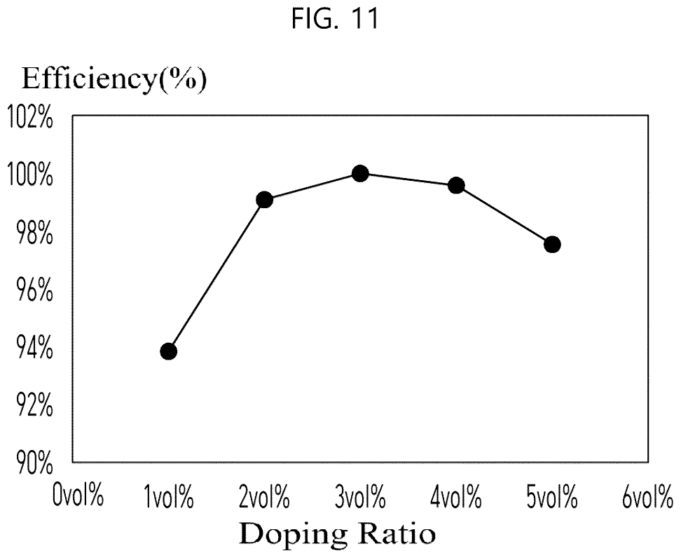

FIG. 9 is a graph showing efficiency of the blue light emitting device depending on a doping amount. FIG. 10 is a graph showing efficiency of a green light emitting device depending on a doping amount. FIG. 11 is a graph showing efficiency of a red light emitting device depending on a doping amount.

As shown in FIGS. 9 to 11, the blue light emitting device has efficiency of a certain level or more in the range of about 1 vol % to 5 vol %, the green light emitting device has efficiency of the certain level or more in the range of about 4 vol % to 13 vol %, and the red light emitting device has efficiency of the certain level or more in the range of about 1 vol % to 5 vol %.

Tables 1 to 4 show that the doping amount for each light emitting device is adjusted to an optimal range, and the effect of applying multiple sub-light emitting layers to each light emitting stack has been confirmed.

Hereinafter, a light emitting display device, in which a plurality of light emitting stacks is applied to each of a blue light emitting device, a green light emitting device, and a red light emitting device, will be described.

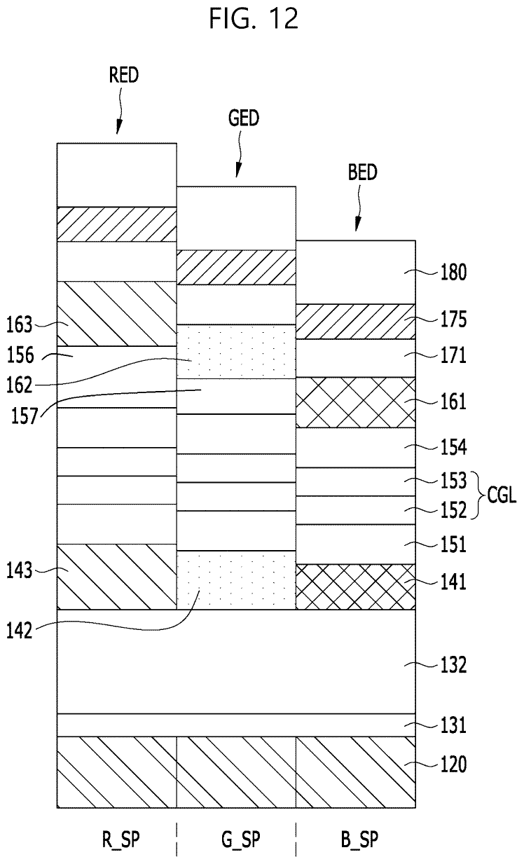

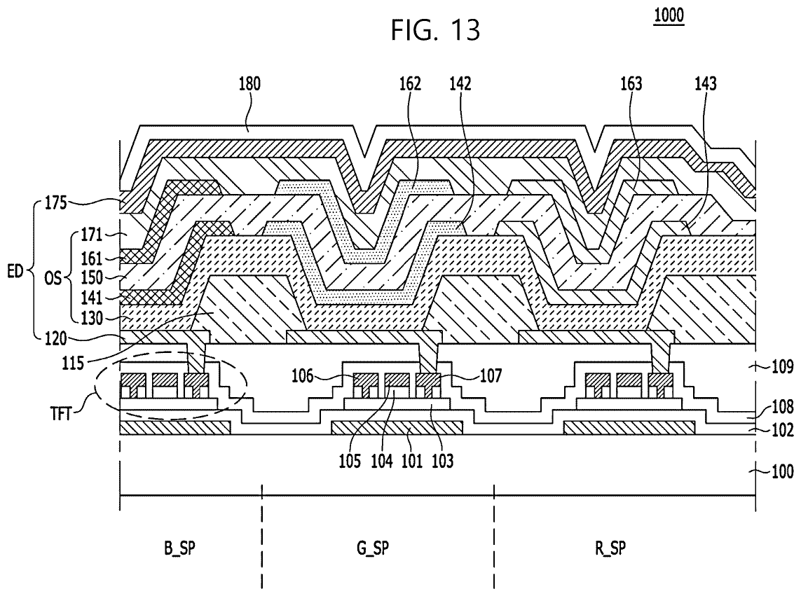

FIG. 12 is a cross-sectional view showing a light emitting display device according to one or more embodiments of the present disclosure. FIG. 13 is a detailed cross-sectional view showing the light emitting display device according to one or more embodiments of the present disclosure.

As shown in FIGS. 12 and 13, a light emitting display device 1000 according to one or more embodiments of the present disclosure includes a substrate 100 including a first subpixel R_SP, a second subpixel G_SP, and a third subpixel B_SP, and light emitting devices RED, GED, and BED provided in the respective subpixels R_SP, G_SP, and B_SP. For example, the light emitting display device 1000 according to one exemplary embodiment of the present disclosure may include a red light emitting device RED provided in the first subpixel R_SP, a green light emitting device GED provided in the second subpixel G_SP, and a blue light emitting device BED provided in the third subpixel B_SP, without being limited thereto.

More specifically, the light emitting display device 1000 according to one or more embodiments of the present disclosure includes a red light emitting device RED provided in the first subpixel R_SP and including first and second light emitting layers 143 and 163, a green light emitting device GED provided in the second subpixel G_SP and including first and second light emitting layers 142 and 162, and a blue light emitting device BED provided in the third subpixel B_SP and including first and second light emitting layers 141 and 161.

In the light emitting display device shown in FIGS. 12 and 13, each light emitting device RED, GED, or BED includes a charge generation layer CGL between first and second electrodes 120 and 175, a lower stack between the first electrode 120 and the charge generation layer CGL, and an upper stack between the charge generation layer CGL and the second electrode 175.

Specifically, the red light emitting device RED includes the charge generation layer CGL between the first electrode 120 and the second electrode 175, and two stacks divided by the charge generation layer CGL, such as the upper stack and the lower stack of the red light emitting device RED. The lower stack of the red light emitting device RED includes a hole injection layer 131, a first hole transport layer 132, the first red light emitting layer 143, and a first electron transport layer 151. The upper stack of the red light emitting device RED includes a second hole transport layer 154, a first hole transport compensation layer 156, the second red light emitting layer 163, and a second electron transport layer 171.

Here, the above-described multiple sub-light emitting layers EMLx1 and EMLx2 can be applied to each or one of the first and second red light emitting layers 143 and 163.

Specifically, the green light emitting device GED includes the charge generation layer CGL between the first electrode 120 and the second electrode 175, and two stacks divided by the charge generation layer CGL, such as the upper stack and the lower stack of the green light emitting device GED. The lower stack of the green light emitting device GED shown in FIG. 12 includes a hole injection layer 131, a first hole transport layer 132, the first green light emitting layer 142, and a first electron transport layer 151. The upper stack of the green light emitting device GED includes a second hole transport layer 154, a second hole transport compensation layer 157, the second green light emitting layer 162, and a second electron transport layer 171.

Here, the above-described multiple sub-light emitting layers EMLx1 and EMLx2 can be applied to each or one of the first and second green light emitting layers 142 and 162.

Specifically, the blue light emitting device BED includes the charge generation layer CGL between the first electrode 120 and the second electrode 175, and two stacks divided by the charge generation layer CGL, such as the upper stack and the lower stack of the blue light emitting device BED. The lower stack of the blue light emitting device BED shown in FIG. 12 includes a hole injection layer 131, a first hole transport layer 132, the first blue light emitting layer 141, and a first electron transport layer 151. The upper stack of the blue light emitting device BED includes a second hole transport layer 154, the second blue light emitting layer 161, and a second electron transport layer 171.

Here, the above-described multiple sub-light emitting layers EMLx1 and EMLx2 can be applied to each or one of the first and second blue light emitting layers 141 and 161.

The first red light emitting layer 143 and the second red light emitting layer 163 overlap each other in the first subpixel R_SP, the first green light emitting layer 142 and the second green light emitting layer 162 overlap each other in the second subpixel R_GP, and the first blue light emitting layer 141 and the second red light emitting layer 161 overlap each other in the third subpixel B_SP.

Further, the charge generation layer CGL in which an n-type charge generation layer 152 and a p-type charge generation layer 153 are stacked is further provided between the lower stack and the upper stack. The n-type charge generation layer 152 generates electrons and supplies and transfers the electrons to the lower stack, and the p-type charge generation layer 153 generates holes and supplies and transfers the holes to the upper stack. In some cases, the n-type charge generation layer 152 and the p-type charge generation layer 153 can be formed as one layer.

All the layers included between the first electrode 120 and the second electrode 175 are referred to as an intermediate layer OS (EL in FIG. 1), and all the layers included in the intermediate layer OS can include organic materials. In some cases, some layers can include small amounts of inorganic materials as dopants to control electron transportability, hole transportability, mobility, or light emission.

In the light emitting display device according to one or more embodiments of the present disclosure, the hole injection layer 131, the first hole transport layer 132, the first electron transport layer 151, the charge generation layer CGL, the second hole transport layer 154, and the second electron transport layer 171 are provided in common throughout the respective light emitting devices RED, GED, and BED, and in this respect, these layers are also referred to as common layers.

The red light emitting device RED, the green light emitting device GED, and the blue light emitting device BED have different vertical distances between the first electrode 120 and the second electrode 175 to obtain different out-coupling properties depending on the wavelength of the color of each emitted light. In order to vary the vertical distance between the first electrode 120 and the second electrode 175, the red light emitting device RED and the green light emitting device GED can have the first hole transport compensation layer 156 and the second hole transport compensation layer 157 having different thicknesses, respectively.

Here, the first hole transport compensation layer 156 and the second hole transport compensation layer 157 can be disposed only in one of the lower stack and the upper stack, or can be disposed in contact with the hole transport layer in each of the lower stack and the upper stack. FIG. 12 shows an example in which the first and second hole transport compensation layers 156 and 157 are disposed in the upper stacks of the red light emitting device RED and the green light emitting device GED. The first and second hole transport compensation layers 156 and 157 can be formed of an organic material having the same or similar energy band gap characteristics as or to the first and second hole transport layers 132 and 154. However, the present disclosure is not limited thereto. However, the present disclosure is not limited thereto.

Further, in the light emitting display device according to one or more embodiments of the present disclosure, one of the first electrode 120 and the second electrode 175 may be a reflective electrode, and the other may be a transparent electrode or a transflective electrode. For example, the first electrode 120 can include a reflective electrode, and the second electrode 175 can be a transflective electrode or a transparent electrode. A capping layer 180 can be further provided on the second electrode 175 to protect the red light emitting device RED, the green light emitting device GED, and the blue light emitting device BED and to increase the luminous efficacy of light emitted from the second electrode 175. The capping layer 180 can include at least one of an organic capping layer or an inorganic capping layer. The capping layer 180 can be formed by stacking a plurality of capping layers having different refractive indexes, thereby being capable of maximizing a light emission effect.

When the light emitting device is a top emission type, the first electrode (e.g., the anode) 120 can include a reflective electrode, and the second electrode (e.g., the cathode) 175 can include a transparent electrode or a transflective electrode. For example, if the first electrode (e.g., the anode) 120 includes a reflective electrode, the first electrode (e.g., the anode) 120 can be formed in a multilayer structure including a transparent conductive film and an opaque conductive film having high reflection efficiency. The transparent conductive film of the first electrode (e.g., the anode) 120 can be formed of a material having a relatively high work function value, such as indium tin oxide (ITO) or indium zinc oxide (IZO), and the opaque conductive film can be formed in a single layer or multiple layers including one selected from the group consisting of silver (Ag), magnesium (Mg), aluminum (Al), copper (Cu), molybdenum (Mo), titanium (Ti), nickel (Ni), chromium (Cr), tungsten (W), and alloys thereof. For example, the first electrode (e.g., the anode) 120 can be formed in a structure in which a transparent conductive film, an opaque conductive film, and a transparent conductive film are sequentially stacked, or in a structure in which a transparent conductive film and an opaque conductive film are sequentially stacked. As an example, the first electrode (e.g., the anode) 120 can include a stacked structure of ITO/Ag—Pd—Cu (APC)/ITO.

The second electrode (e.g., the cathode) 175 can be formed of, for example, a transparent conductive material, such as indium tin oxide (ITO) or indium zinc oxide (IZO), or formed of silver (Ag), magnesium (Mg), calcium (Ca), ytterbium (Yb), or an alloy including at least one thereof, to have a small enough thickness to transmit light. If the second electrode (e.g., the cathode) 175 is formed of a metal or a metal alloy to have a small enough thickness to transmit light, the second electrode (e.g., the cathode) 175 is transflective, and thus allows light resonated between the first electrode (e.g., the anode) 120 and the second electrode (e.g., the cathode) 175 to be transmitted through the second electrode (e.g., the cathode) 175 while having strong cavity characteristics.

Further, the light emitting display device according to one or more embodiments of the present disclosure can have different optical distances of the red light emitting device RED, the green light emitting device GED, and the blue light emitting device BED by varying the thickness of the first and second red light emitting layers 143 and 163, the thickness of the first and second green light emitting layers 142 and 162, and the thickness of the first and second blue light emitting layers 141 and 161, which are adjacent to each other.

Each of the red light emitting device RED, the green light emitting device GED, and the blue light emitting device BED includes the first electrode 120 and the second electrode 175 facing each other. The red light emitting device RED may include the first and second red light emitting layers 143 and 163 between the first electrode 120 and the second electrode 175. The green light emitting device GED may include the first and second green light emitting layers 142 and 162 between the first electrode 120 and the second electrode 175. The blue light emitting device BED may include the first and second blue light emitting layers 141 and 161 between the first electrode 120 and the second electrode 175. Further, the red light emitting device RED, the green light emitting device GED, and the blue light emitting device BED have different vertical distances between the inner surface (the surface in contact with the hole injection layer 131) of the first electrode 120 and the inner surface (the surface in contact with the electron transport layer 171) of the second electrode 175, and can obtain the maximum out-coupling characteristics of each emission color due to differences in the vertical distance between the first and second electrodes 120 and 175.

The maximum out-coupling characteristics are obtained under conditions in which light generated from the light emitting layers between the first and second electrodes 120 and 175 of each light emitting device is reflected and re-reflected on the inner surfaces of the first and second electrodes 120 and 175 so that light emission can be maximized through constructive interference. The red light emitting device RED has a maximum emission peak at a wavelength of 600 nm to 650 nm, the green light emitting device GED has a maximum emission peak at a wavelength of 500 nm to 590 nm, and the blue light emitting device BED has a maximum emission peak at a wavelength of 420 nm to 490 nm. For example, the red light emitting device RED, the green light emitting device GED, and the blue light emitting device BED have different wavelengths at which each maximum emission peak occurs, and thus have different vertical distances between the first and second electrodes 120 and 175 required for out-coupling characteristics through constructive interference.

At least the blue light emitting device among the light emitting devices according to one or more embodiments of the present disclosure must increase the average dopant content of the first light emitting layer closer to the anode in order to increase the efficiency effect within a range that does not cause an inflection section, and it can be seen that, if multiple sub-light emitting layers are applied to the light emitting layer in each light emitting stack in the blue light emitting device, efficiency is improved when the dopant content of the second sub-light emitting layer close to the cathode is high, as shown in the results of Table 2.

In addition, the green light emitting device or the red light emitting device including a phosphorescent material has low sensitivity to occurrence of an inflection section, and thus, efficiency can be improved by increasing the average dopant content of an n^{th} light emitting layer closer to the cathode.

Further, in a structure in which light emitting layers that commonly emit light of the same color are applied to a plurality of light emitting stacks, when each light emitting layer has a stacked structure of multiple sub-light emitting layers, increase in the doping amount of the upper sub-light emitting layer can further contribute to efficiency increase.

The light emitting device according to one or more embodiments of the present disclosure, when each light emitting layer has a stacked structure of multiple sub-light emitting layers in a structure in which light emitting layers that commonly emit light of the same color are applied to a plurality of light emitting stacks, can increase the doping amount of the upper sub-light emitting layer compared to the doping amount of the lower sub-light emitting layer to further contribute to efficiency increase.

The light emitting device according to one or more embodiments of the present disclosure can increase the average dopant content of the first light emitting layer closer to the anode than the average dopant content of other light emitting layers close to the cathode in at least the blue light emitting device, thereby being capable of increasing the efficiency effect within a range that does not cause an inflection section.

The light emitting device according to one or more embodiments of the present disclosure can increase the average dopant content of an n^{th} light emitting layer closer to the cathode than the average dopant content of the first light emitting layer close to the anode in the green light emitting device or the red light emitting device including a phosphorescent material, thereby being capable of increasing efficiency.

A light emitting device according to one or more embodiments of the present disclosure can comprise an anode, a plurality of light emitting stacks to overlap with a charge generation layer interposed therebetween on the anode; and a cathode on the plurality of light emitting stacks. Each of the plurality of light emitting stacks can comprise a light emitting layer to emit light of a color of the same series. The light emitting layer of at least one of the plurality of light emitting stacks can comprise a first sub-light emitting layer and a second sub-light emitting layer in contact with each other. The second sub-light emitting layer can have a greater dopant content than the first sub-light emitting layer.

In a light emitting device according to one or more embodiments of the present disclosure, an average dopant content of the light emitting layer of a light emitting stack closest to the anode and an average dopant content of the light emitting layer of a light emitting stack closest to the cathode can be different.

In a light emitting device according to one or more embodiments of the present disclosure, the light emitting layer can emit blue light and an average doping amount of the light emitting layer of a light emitting stack closest to the anode can be greater than an average doping amount of the light emitting layer of a light emitting stack closest to the cathode.

In a light emitting device according to one or more embodiments of the present disclosure, a maximum PL wavelength of the light emitting layer of the light emitting stack closest to the cathode can be shorter than a maximum PL wavelength of the light emitting layer of the light emitting stack closest to the anode.

In a light emitting device according to one exemplary embodiment of the present disclosure, the light emitting layer may emit green light; and an average doping amount of the light emitting layer of a light emitting stack closest to the cathode may be greater than or equal to an average doping amount of the light emitting layer of a light emitting stack closest to the anode.

In a light emitting device according to one exemplary embodiment of the present disclosure, the light emitting layer may emit red light; and an average doping amount of the light emitting layer of a light emitting stack closest to the cathode may be greater than or equal to an average doping amount of the light emitting layer of a light emitting stack closest to the anode.

In a light emitting device according to one or more embodiments of the present disclosure, the light emitting layer can emit light of a color with a longer wavelength than blue light and an average doping amount of the light emitting layer of a light emitting stack closest to the cathode can be greater than or equal to an average doping amount of the light emitting layer of a light emitting stack closest to the anode.

In a light emitting device according to one or more embodiments of the present disclosure, the second sub-light emitting layer can be closer to the cathode than the first sub-light emitting layer. An emission peak of the second sub-light emitting layer can have a longer wavelength than an emission peak of the first sub-light emitting layer.

In a light emitting device according to one or more embodiments of the present disclosure, the second sub-light emitting layer can be closer to the cathode than the first sub-light emitting layer, a LUMO energy level of a host of the second sub-light emitting layer can be higher than or equal to a LUMO energy level of a host of the first sub-light emitting layer and a HOMO energy level of the host of the second sub-light emitting layer can be higher than or equal to a HOMO energy level of the host of the first sub-light emitting layer.

In a light emitting device according to one or more embodiments of the present disclosure, a PL peak of a dopant of the second sub-light emitting layer can be smaller than a PL peak of a dopant of the first sub-light emitting layer.

In a light emitting device according to one or more embodiments of the present disclosure, the anode can comprise a reflective electrode and the cathode can comprise a transparent electrode or a transflective electrode.

A light emitting display device according to one or more embodiments of the present disclosure can comprise a blue light emitting device, a green light emitting device, and a red light emitting device at a first subpixel, a second subpixel, and a third subpixel on a substrate, each of the blue, green, and red light emitting devices comprising a plurality of light emitting stacks between an anode and a cathode. At least one of the blue light emitting device, the green light emitting device, and the red light emitting device can comprise a first sub-light emitting layer and a second sub-light emitting layer in contact with each other in at least one of the plurality of light emitting stacks.

In a light emitting display device according to one or more embodiments of the present disclosure, the second sub-light emitting layer can have a greater dopant content than the first sub-light emitting layer.

In a light emitting display device according to one or more embodiments of the present disclosure, the blue light emitting device can comprise a blue light emitting layer in each of the plurality of light emitting stacks, and an average dopant content of the blue light emitting layer of a light emitting stack closest to the anode can be greater than and an average dopant content of the blue light emitting layer of a light emitting stack closest to the cathode.

In a light emitting display device according to one or more embodiments of the present disclosure, the green light emitting device can comprise a green light emitting layer in each of the plurality of light emitting stacks, and an average dopant content of the green light emitting layer of a light emitting stack closest to the cathode can be greater than and an average dopant content of the green light emitting layer of a light emitting stack closest to the anode.

In a light emitting display device according to one or more embodiments of the present disclosure, the red light emitting device can comprise a red light emitting layer in each of the plurality of light emitting stacks, and an average dopant content of the red light emitting layer of a light emitting stack closest to the cathode can be greater than and an average dopant content of the red light emitting layer of a light emitting stack closest to the anode.

In a light emitting display device according to one or more embodiments of the present disclosure, the second sub-light emitting layer can be closer to the cathode than the first sub-light emitting layer and an emission peak of the second sub-light emitting layer can have a longer wavelength than an emission peak of the first sub-light emitting layer.

In a light emitting display device according to one or more embodiments of the present disclosure, the second sub-light emitting layer can be closer to the cathode than the first sub-light emitting layer. A LUMO energy level of a host of the second sub-light emitting layer can be higher than or equal to a LUMO energy level of a host of the first sub-light emitting layer. A HOMO energy level of the host of the second sub-light emitting layer can be higher than or equal to a HOMO energy level of the host of the first sub-light emitting layer.

In a light emitting display device according to one or more embodiments of the present disclosure, a PL peak of a dopant of the second sub-light emitting layer can be smaller than a PL peak of a dopant of the first sub-light emitting layer.

In a light emitting display device according to one or more embodiments of the present disclosure, an emission peak of the second sub-light emitting layer can have a longer wavelength than an emission peak of the first sub-light emitting layer.

In a light emitting display device according to one or more embodiments of the present disclosure, the anode can comprise a reflective electrode and the cathode can comprise a transparent electrode or a transflective electrode.

As is apparent from the above description, a light emitting device and a light emitting display device including the same according to one or more embodiments of the present disclosure have the following effects.

The light emitting device according to one or more embodiments of the present disclosure, when each light emitting layer has a stacked structure of multiple sub-light emitting layers in a structure in which light emitting layers that commonly emit light of the same color are applied to a plurality of light emitting stacks, can increase the doping amount of the upper sub-light emitting layer compared to the doping amount of the lower sub-light emitting layer to further contribute to efficiency increase.

The light emitting device according to one or more embodiments of the present disclosure can increase the average dopant content of a first light emitting layer closer to an anode compared to the average dopant content of other light emitting layers close to a cathode in at least a blue light emitting device to increase the efficiency effect within a range that does not cause occurrence of an inflection section.

The light emitting device according to one or more embodiments of the present disclosure can increase the average dopant content of an n^{th} light emitting layer closer to the cathode than the average dopant content of the first light emitting layer close to the anode in a green light emitting device or a red light emitting device including a phosphorescent material to increase efficiency.

The light emitting device according to one or more embodiments of the present disclosure can maximize efficiency through adjustment of dopant contents of a plurality of light emitting layers or characteristics of hosts in the light emitting layers in a tandem structure in which light emitting layers configured to emit light of the same color for each light emitting device overlap. Further, the light emitting device according to one or more embodiments of the present disclosure can prevent occurrence of an inflection section to improve visibility. Consequently, the light emitting device according to one or more embodiments of the present disclosure can reduce power consumption, and can simultaneously have the effects of high efficiency, high luminance, and high color reproduction to achieve environmental, social, and governance (ESG) effects.

It will be apparent to those skilled in the art that various modifications and variations can be made in the present disclosure without departing from the spirit or scope of the disclosure. Thus, it is intended that the present disclosure cover the modifications and variations of the present disclosure provided they come within the scope of the appended claims and their equivalents.

What is claimed is:

1. A light emitting device comprising:
an anode;
a plurality of light emitting stacks to overlap with a charge generation layer interposed therebetween on the anode; and
a cathode on the plurality of light emitting stacks,
wherein:
each of the plurality of light emitting stacks comprises a light emitting layer to emit light of a color of same series;
the light emitting layer of at least one of the plurality of light emitting stacks comprises a first sub-light emitting layer and a second sub-light emitting layer in contact with each other; and
the second sub-light emitting layer has a greater dopant content than the first sub-light emitting layer.

2. The light emitting device according to claim 1, wherein an average dopant content of the light emitting layer of a light emitting stack closest to the anode and an average dopant content of the light emitting layer of a light emitting stack closest to the cathode are different from each other.

3. The light emitting device according to claim 1, wherein:
at least one of the light emitting layers emits blue light; and
an average doping amount of the light emitting layer of a light emitting stack closest to the anode is greater than an average doping amount of the light emitting layer of a light emitting stack closest to the cathode.

4. The light emitting device according to claim 3, wherein a maximum photoluminescence (PL) wavelength of the light emitting layer of the light emitting stack closest to the cathode is shorter than a maximum PL wavelength of the light emitting layer of the light emitting stack closest to the anode.

5. The light emitting device according to claim 1, wherein:
at least one of the light emitting layers emits light of a color having a longer wavelength than blue light; and
an average doping amount of the light emitting layer of a light emitting stack closest to the cathode is greater than or equal to an average doping amount of the light emitting layer of a light emitting stack closest to the anode.

6. The light emitting device according to claim 1, wherein:
the second sub-light emitting layer is closer to the cathode than the first sub-light emitting layer; and
an emission peak of the second sub-light emitting layer has a longer wavelength than an emission peak of the first sub-light emitting layer.

7. The light emitting device according to claim 1, wherein:
the second sub-light emitting layer is closer to the cathode than the first sub-light emitting layer;
a Lowest Unoccupied Molecular Orbital (LUMO) energy level of a host of the second sub-light emitting layer is higher than or equal to a LUMO energy level of a host of the first sub-light emitting layer; and
a Highest Occupied Molecular Orbital (HOMO) energy level of the host of the second sub-light emitting layer is higher than or equal to a HOMO energy level of the host of the first sub-light emitting layer.

8. The light emitting device according to claim 1, wherein a photoluminescence (PL) peak of a dopant of the second sub-light emitting layer is smaller than a PL peak of a dopant of the first sub-light emitting layer.

9. The light emitting device according to claim 1, wherein:
the anode comprises a reflective electrode; and
the cathode comprises a transparent electrode or a transflective electrode.

10. A light emitting device comprising:
an anode;
a plurality of light emitting stacks to overlap with a charge generation layer interposed therebetween on the anode; and
a cathode on the plurality of light emitting stacks,
wherein:
each of the plurality of light emitting stacks comprises a light emitting layer to emit light of a color of the same series;
the light emitting layer of at least one of the plurality of light emitting stacks comprises a first sub-light emitting layer and a second sub-light emitting layer in contact with each other; and
an average dopant content of the light emitting layer of a light emitting stack closest to the anode and an average dopant content of the light emitting layer of a light emitting stack closest to the cathode are different.

11. A light emitting display device comprising:
a blue light emitting device, a green light emitting device, and a red light emitting device disposed respectively at a first subpixel, a second subpixel, and a third subpixel on a substrate,
each of the blue, green, and red light emitting devices comprising a plurality of light emitting stacks between an anode and a cathode,
wherein at least one of the blue light emitting device, the green light emitting device, and the red light emitting device comprises a first sub-light emitting layer and a second sub-light emitting layer in contact with each other in at least one of the plurality of light emitting stacks.

12. The light emitting display device according to claim 11, wherein the second sub-light emitting layer has a greater dopant content than the first sub-light emitting layer.

13. The light emitting display device according to claim 11, wherein:
the blue light emitting device comprises a blue light emitting layer in each of the plurality of light emitting stacks; and
an average dopant content of the blue light emitting layer of a light emitting stack closest to the anode is greater than and an average dopant content of the blue light emitting layer of a light emitting stack closest to the cathode.

14. The light emitting display device according to claim 13, wherein:
the green light emitting device comprises a green light emitting layer in each of the plurality of light emitting stacks; and
an average dopant content of the green light emitting layer of a light emitting stack closest to the cathode is greater than and an average dopant content of the green light emitting layer of a light emitting stack closest to the anode.

15. The light emitting display device according to claim 13, wherein:
the red light emitting device comprises a red light emitting layer in each of the plurality of light emitting stacks; and
an average dopant content of the red light emitting layer of a light emitting stack closest to the cathode is greater than and an average dopant content of the red light emitting layer of a light emitting stack closest to the anode.

16. The light emitting display device according to claim 11, wherein:
the second sub-light emitting layer is closer to the cathode than the first sub-light emitting layer; and
an emission peak of the second sub-light emitting layer has a longer wavelength than an emission peak of the first sub-light emitting layer.

17. The light emitting display device according to claim 11, wherein:
the second sub-light emitting layer is closer to the cathode than the first sub-light emitting layer;
a Lowest Unoccupied Molecular Orbital (LUMO) energy level of a host of the second sub-light emitting layer is higher than or equal to a LUMO energy level of a host of the first sub-light emitting layer; and
a Highest Occupied Molecular Orbital (HOMO) energy level of the host of the second sub-light emitting layer is higher than or equal to a HOMO energy level of the host of the first sub-light emitting layer.

18. The light emitting display device according to claim 11, wherein a photoluminescence (PL) peak of a dopant of the second sub-light emitting layer is smaller than a PL peak of a dopant of the first sub-light emitting layer.

19. The light emitting display device according to claim 11, wherein an emission peak of the second sub-light emitting layer has a longer wavelength than an emission peak of the first sub-light emitting layer.

20. The light emitting display device according to claim 11, wherein:
the anode comprises a reflective electrode; and
the cathode comprises a transparent electrode or a transflective electrode.
